(19) United States
(12) Patent Application Publication
(10) Pub. No.: US 2025/0254909 A1
(43) Pub. Date: Aug. 7, 2025

(54) POWER SEMICONDUCTOR DEVICES INCLUDING INTEGRATED POLYSILICON DEVICES

(71) Applicant: Wolfspeed, Inc., Durham, NC (US)

(72) Inventors: Woongsun Kim, Cary, NC (US); Naeem Islam, Morrisville, NC (US); Madankumar Sampath, Morrisville, NC (US); Sei-Hyung Ryu, Cary, NC (US)

(21) Appl. No.: 18/430,542

(22) Filed: Feb. 1, 2024

(51) Int. Cl. H01L 29/78; H01L 29/49

(52) U.S. Cl. CPC H10D 30/668; H10D 64/661

(57) ABSTRACT

A power semiconductor device includes a semiconductor structure comprising an active region, a plurality of gates that extend in a first direction in or on the active region of the semiconductor structure, at least one integrated polysilicon device in or on the semiconductor structure adjacent the active region, and a gate connector electrically connecting the plurality of gates. The gate connector is in or on the semiconductor structure between the at least one integrated polysilicon device and the plurality of gates. The at least one integrated polysilicon device is electrically isolated from the gate connector devoid of an inter-polysilicon dielectric layer therebetween. Related devices and fabrication methods are also discussed.

### FIELD

The present disclosure relates to power semiconductor devices and methods of fabricating power semiconductor devices.

### BACKGROUND

Power semiconductor devices are used to carry large currents and support high voltages. A wide variety of power semiconductor devices may be used in the art, including, for example, power Metal Oxide Semiconductor Field Effect Transistors (MOSFET), bipolar junction transistors (BJT), Insulated Gate Bipolar Transistors (IGBT), Junction Barrier Schottky diodes, Gate Turn-Off Transistors (GTO), MOS-controlled thyristors and various other devices. These power semiconductor devices are generally fabricated from wide band-gap semiconductor materials, such as silicon carbide (SiC) or gallium nitride (GaN) based semiconductor materials. Herein, a wide band-gap semiconductor material refers to a semiconductor material having a band-gap greater than about 1.40 eV, for example, greater than about 2 eV.

Power semiconductor devices can have a lateral structure or a vertical structure. In a device having a lateral structure, the terminals of the device (e.g., the drain, gate and source terminals for a power MOSFET device) are on the same major surface (e.g., top or bottom) of a semiconductor structure. In contrast, in a device having a vertical structure, at least one terminal is provided on each major surface of the semiconductor structure. For example, in a vertical MOSFET device, the source may be on the top surface of the semiconductor structure and the drain may be on the bottom surface of the semiconductor structure. As another example, power Schottky diodes typically have a vertical structure where the anode contact is formed on a first major surface (e.g., the top surface) of a semiconductor structure, and the cathode contact is formed on the other major surface (e.g., the bottom surface). Vertical structures are typically used in very high power applications, as the vertical structure allows for a thick semiconductor drift layer or region that can support high current densities and block high voltages. The semiconductor structure may or may not include an underlying substrate. Herein, the term “semiconductor structure” refers to a structure that includes one or more semiconductor layers, such as semiconductor substrates and/or semiconductor epitaxial layers.

Vertical power semiconductor devices that include a MOSFET transistor can have a standard gate electrode design in which the gate electrode of the transistor is formed on top of the semiconductor structure (also referred to as a planar gate configuration) or, alternatively, may have the gate electrode buried in a trench within the semiconductor structure (also referred to as a trench gate configuration or gate trench MOSFET). With the standard gate electrode design, the channel region of each unit cell transistor is horizontally disposed underneath the gate electrode. In contrast, in the gate trench MOSFET design, the channel is vertically disposed. For example, a SiC trench MOSFET may provide an inherent lower specific on-resistance due to obtaining a relatively narrow cell pitch by implementing the channel area on the sidewalls of the trench. Channel mobility on the trench sidewalls may also be significantly (e.g., two to four times) greater than the planar Si-face, resulting in enhanced current density. Gate trench MOSFETs may thus provide enhanced performance, but typically require a more complex manufacturing process.

More generally, a conventional power semiconductor device typically includes a semiconductor substrate, such as a silicon carbide substrate, having a first conductivity type (e.g., an n-type substrate) on which an epitaxial layer structure having the first conductivity type (e.g., n-type) is formed. A portion of this epitaxial layer structure (which may comprise one or more separate layers) functions as a drift region of the power semiconductor device. The device typically includes an “active region,” which includes one or more power semiconductor devices that have a junction, such as a p-n junction or a Schottky junction. The active region may be formed on and/or in the drift region. The active region acts as a main junction for blocking voltage in the reverse bias direction and providing current flow in the forward bias direction. The power semiconductor device may also have an edge termination in a termination region that is adjacent the active region. One or more power semiconductor devices may be formed on the substrate, and each power semiconductor device will typically have its own edge termination. After the substrate is fully processed, the resultant structure may be diced to separate the individual edge-terminated power semiconductor devices. The power semiconductor devices may have a unit cell structure in which the active region of each power semiconductor device includes a plurality of individual “unit cell” structures that are disposed in parallel to each other and that together can function as a single power semiconductor device.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. However, as the applied voltage approaches or passes the voltage level that the device is designed to block, non-trivial levels of current may begin to flow through the power semiconductor device. Such current, which is typically referred to as “leakage current,” may be highly undesirable. Leakage current may begin to flow if the voltage is increased beyond the design voltage blocking capability of the device, which may be a function of, among other things, the doping and thickness of the drift region. Leakage currents may also arise for other reasons, such as failure of the edge termination and/or the primary junction of the device. If the voltage applied to the device is increased past the breakdown voltage to a critical level, the increasing electric field may result in an uncontrollable and undesirable runaway generation of charge carriers within the semiconductor device, leading to a condition known as avalanche breakdown.

Power semiconductor devices may also include additional integrated semiconductor devices (e.g., diodes, transistors) on the semiconductor structure outside (e.g., laterally adjacent to) the active region. For example, some power semiconductor devices may include integrated temperature sensors on a peripheral region of the semiconductor structure, adjacent to the active region. The fabrication of such additional integrated semiconductor devices may thus require additional insulating layer and/or semiconductor layer fabrication processes, which may require increased cell pitch and/or may present inefficiencies in manufacturing.

### SUMMARY

According to some embodiments of the present disclosure, a power semiconductor device includes a semiconductor structure comprising an active region, a plurality of gates that extend in a first direction in or on the active region of the semiconductor structure, at least one integrated polysilicon device in or on a surface of the semiconductor structure adjacent the active region, and a gate connector electrically connecting the plurality of gates. The gate connector is in or on the surface of the semiconductor structure laterally between the at least one integrated polysilicon device and the plurality of gates. The at least one integrated polysilicon device is electrically isolated from the gate connector devoid of an inter-polysilicon dielectric layer therebetween.

In some embodiments, the at least one integrated polysilicon device does not overlap with the gate connector in a direction perpendicular to the surface of the semiconductor structure.

In some embodiments, the at least one integrated polysilicon device comprises a surface that is coplanar with a surface of the gate connector.

In some embodiments, the at least one integrated polysilicon device and the gate connector comprise portions of a same polysilicon layer.

In some embodiments, an isolation layer is provided on the surface of the semiconductor structure. The at least one integrated polysilicon device is on the isolation layer devoid of the inter-polysilicon dielectric layer therebetween.

In some embodiments, an inter-metal dielectric layer is provided on the gate connector and the at least one integrated polysilicon device. Respective conductive vias extend through the inter-metal dielectric layer by a same depth to electrically contact the gate connector and the at least one integrated polysilicon device.

In some embodiments, the plurality of gates respectively comprise first and second portions that extend in a first direction in respective gate trenches in the active region, and the gate connector has a different conductivity than the first portions.

In some embodiments, the first portions of the plurality of gates comprise a greater dopant concentration than the second portions, and the gate connector comprises a same dopant concentration as the second portions of the plurality of gates.

In some embodiments, the plurality of gates extend in respective gate trenches in the active region, and the at least one integrated polysilicon device extends in a trench in the semiconductor structure adjacent the active region.

In some embodiments, the plurality of gates extend in respective gate trenches in the active region, and the at least one integrated polysilicon device comprises a planar surface on the surface of the semiconductor structure adjacent the active region.

In some embodiments, the plurality of gates comprise respective planar surfaces on the active region, and the at least one integrated polysilicon device extends in a trench in the semiconductor structure adjacent the active region.

According to some embodiments of the present disclosure, a power semiconductor device includes a semiconductor structure comprising an active region, a plurality of gates that extend in a first direction in or on the active region of the semiconductor structure, a gate connector electrically connecting the plurality of gates, and at least one integrated polysilicon device in or on the semiconductor structure adjacent the gate connector. The at least one integrated polysilicon device and the gate connector comprise respective surfaces that are coplanar.

In some embodiments, the respective surfaces of the at least one integrated polysilicon device and the gate connector comprise portions of a same polysilicon layer.

In some embodiments, the at least one integrated polysilicon device is electrically isolated from the gate connector devoid of an inter-polysilicon dielectric layer therebetween.

In some embodiments, an isolation layer is provided on the semiconductor structure adjacent the active region. The at least one integrated polysilicon device is on the isolation layer devoid of the inter-polysilicon dielectric layer therebetween.

In some embodiments, the plurality of gates respectively comprise first and second portions that extend in a first direction in respective gate trenches in the active region, and the gate connector has a different conductivity than the first portions.

In some embodiments, an inter-metal dielectric layer is provided on the gate connector and the at least one integrated polysilicon device. Respective conductive vias extend through the inter-metal dielectric layer by a same depth to electrically contact the gate connector and the at least one integrated polysilicon device.

According to some embodiments of the present disclosure, a power semiconductor device includes a semiconductor structure comprising an active region, a plurality of gates that extend in a first direction in or on the active region of the semiconductor structure, a gate connector electrically connecting the plurality of gates, at least one integrated polysilicon device in or on the semiconductor structure adjacent the gate connector, an inter-metal dielectric layer on the gate connector and the at least one integrated polysilicon device, and respective conductive vias that extend through the inter-metal dielectric layer by a same depth to electrically contact the gate connector and the at least one integrated polysilicon device.

In some embodiments, the at least one integrated polysilicon device comprises a surface that is coplanar with a surface of the gate connector.

In some embodiments, respective contacts are provided on a surface of the inter-metal dielectric layer opposite the semiconductor structure and electrically connected to the respective conductive vias, wherein the surface of the inter-metal dielectric layer is substantially planar.

In some embodiments, the at least one integrated polysilicon device and the gate connector comprise portions of a same polysilicon layer.

In some embodiments, the at least one integrated polysilicon device is electrically isolated from the gate connector devoid of an inter-polysilicon dielectric layer therebetween.

In some embodiments, an isolation layer is provided on the semiconductor structure adjacent the active region. The at least one integrated polysilicon device is on the isolation layer devoid of an inter-polysilicon dielectric layer therebetween.

In some embodiments, the plurality of gates respectively comprise first and second portions that extend in a first direction in respective gate trenches in the active region, and the gate connector has a different conductivity than the first portions.

According to some embodiments of the present disclosure, a power semiconductor device includes a semiconductor structure comprising an active region, a plurality of gates that extend in a first direction in respective trenches in the active region of the semiconductor structure, at least one integrated polysilicon device in or on the semiconductor structure adjacent the plurality of gates, and a gate connector electrically connecting the plurality of gates. The gate connector is in or on the semiconductor structure between the at least one integrated polysilicon device and the plurality of gates. The plurality of gates respectively comprise first and second portions in the respective trenches, and the gate connector has a different conductivity than the first portions.

In some embodiments, the first portions of the gates have a greater conductivity than the second portions of the gates.

In some embodiments, the first portions of the gates comprise doped polysilicon, and wherein the second portions of the gates comprise undoped polysilicon.

In some embodiments, the at least one integrated polysilicon device, the gate connector, and the second portions of the gates comprise portions of a same polysilicon layer.

In some embodiments, the gate connector has a same conductivity as the second portions of the gates.

In some embodiments, the at least one integrated polysilicon device is electrically isolated from the gate connector devoid of an inter-polysilicon dielectric layer therebetween.

In some embodiments, the at least one integrated polysilicon device comprises a surface that is coplanar with a surface of the gate connector.

In some embodiments, an inter-metal dielectric layer is provided on the gate connector and the at least one integrated polysilicon device, and respective conductive vias extend through the inter-metal dielectric layer by a same depth to electrically contact the gate connector and the at least one integrated polysilicon device.

According to some embodiments of the present disclosure, a method of fabricating a power semiconductor device includes forming a polysilicon layer on a semiconductor structure adjacent an active region, and patterning the polysilicon layer to form a gate connector and at least one integrated polysilicon device. The gate connector electrically connects a plurality of gates extending in a first direction in or on the active region. The at least one integrated polysilicon device is in or on the semiconductor structure adjacent the active region.

In some embodiments, the at least one integrated polysilicon device is electrically isolated from the gate connector devoid of an inter-polysilicon dielectric layer therebetween.

In some embodiments, the method includes forming an isolation layer on the semiconductor structure adjacent the active region prior to forming the polysilicon layer thereon, where the at least one integrated polysilicon device is on the isolation layer devoid of the inter-polysilicon dielectric layer therebetween.

In some embodiments, the at least one integrated polysilicon device and the gate connector comprise respective surfaces of the polysilicon layer, and the respective surfaces are coplanar.

In some embodiments, the method further includes forming an inter-metal dielectric layer on the gate connector and the at least one integrated polysilicon device, and forming respective conductive vias that extend through the inter-metal dielectric layer by a same depth to electrically contact the gate connector and the at least one integrated polysilicon device.

In some embodiments, the method further includes forming respective contacts on a surface of the inter-metal dielectric layer opposite the semiconductor structure and electrically connected to the respective conductive vias, where the surface of the inter-metal dielectric layer is substantially planar.

In some embodiments, the method further includes implanting dopants into one or more portions of the polysilicon layer, where the gate connector comprises a same dopant concentration as at least a portion of the plurality of gates.

In some embodiments, the method further includes forming respective gate trenches that extend in the first direction in the active region of the semiconductor structure prior to forming the polysilicon layer thereon. Forming the polysilicon layer includes forming the polysilicon layer extending into the respective gate trenches and onto the semiconductor structure adjacent the active region, and patterning the polysilicon layer forms the plurality of gates in the respective gate trenches.

In some embodiments, the plurality of gates respectively comprise first and second portions that extend in the first direction in the respective gate trenches, and the gate connector has a different conductivity than the first portions.

In some embodiments, the polysilicon layer is a second polysilicon layer, and the method further includes forming a first polysilicon layer extending into the respective gate trenches, patterning the first polysilicon layer to form the first portions of the plurality of gates, and forming the second polysilicon layer on the first portions of the plurality of gates in the respective gate trenches. Patterning the polysilicon layer includes patterning the second polysilicon layer to form the second portions of the plurality of gates, the gate connector, and the at least one integrated polysilicon device. The first polysilicon layer comprises a greater dopant concentration than the second polysilicon layer.

In some embodiments, the first polysilicon layer comprises doped polysilicon, and the second polysilicon layer comprises undoped polysilicon.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a schematic plan view of a power semiconductor device according to some embodiments of the present disclosure.

FIGS. 2 and 3 are schematic cross-sectional views illustrating example power semiconductor devices according to some embodiments of the present disclosure.

FIGS. 4A and 4B are schematic plan views illustrating example power semiconductor devices according to some embodiments of the present disclosure.

FIGS. 5A, 5B, 5C, 5D, 5E, 5F, 5G, 5H, and 5I are schematic cross-sectional views illustrating intermediate fabrication steps in methods of fabricating a power semiconductor device according to some embodiments of the present disclosure.

FIGS. 6A, 6B, 6C, 6D, 6E, 6F, 6G, and 6H are schematic cross-sectional views illustrating intermediate fabrication steps in methods of fabricating a power semiconductor device according to further embodiments of the present disclosure.

FIG. 7 is a flowchart diagram illustrating methods of fabricating a power semiconductor device according to some embodiments of the present disclosure.

FIGS. 8A and 8B are schematic cross-sectional and plan views, respectively, illustrating a conventional power semiconductor device including a trenched gate transistor devices and integrated polysilicon temperature sensors.

### DETAILED DESCRIPTION OF EMBODIMENTS

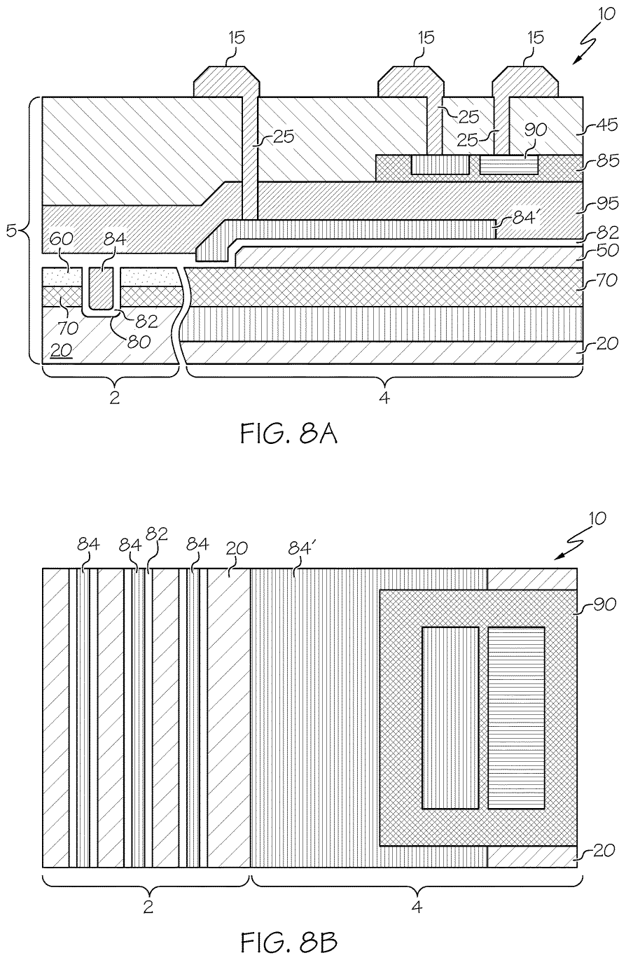

FIG. 8A is a schematic cross-sectional view and FIG. 8B is a schematic plan view illustrating a semiconductor structure 5 of a conventional power semiconductor device 10 including a trenched gate transistor devices and integrated polysilicon (poly-Si) temperature sensors. An active region 2 of the semiconductor structure 5 (which provides an active conduction area for a plurality of transistors) includes a drift region 20, well regions 70 in or on the drift region 20 on a substrate, and source regions 60 on the well region 70 opposite the drift region 20. A source contact (not shown) may be electrically connected to the source regions 60 at the top of the illustrated device 10, and a drain contact (not shown) may be electrically connected to the substrate or the drift region 120 at the bottom of the illustrated device 10. A gate trench 80 extends through the well regions 70 into the drift region, and includes a gate insulating layer 82 and a gate electrode 84 (referred to hereinafter as a gate) therein. A gate runner 84′ (also referred to herein as a gate connector) electrically connects multiple gates 84, and extends onto an isolation layer 150 in a peripheral region 4 of the semiconductor structure 5, which is laterally adjacent to the active region 2. One or more integrated polysilicon devices (illustrated as integrated temperature sensors 90) are provided in the peripheral region 4, and are electrically isolated from the gate runner 84′ by an inter-polysilicon dielectric layer 95 (e.g., an inter-poly oxide (IPO) layer). Respective conductive vias 25 extend through an inter-metal dielectric (IMD) layer 45 to electrically connect the integrated temperature sensors 90 and the gate connector 84′ to respective contacts 15.

In the device 10 shown in FIGS. 8A and 8B, the poly-Si layer 85 used to fabricate the temperature sensors 90 is formed separately from (and vertically overlapping with) the poly-Si layer that is used to fabricate the gates 84 and the gate runner 84′, and is separately processed to form p-type and/or n-type regions therein. As such, some conventional device fabrication methods may require formation of the IPO layer 95 in order to electrically isolate the gates 84 and/or the gate runner 84′ from the overlying temperature sensors 90, as well as some additional fabrication processes, such as poly-Si deposition and etching, after forming the IPO 95.

Some embodiments of the present disclosure may arise from realization that, to improve process efficiency and reduce cell pitch, a poly-Si device can be formed in a peripheral region of a semiconductor structure (e.g., a region that is laterally adjacent to or otherwise outside of the active region) using a poly-Si layer that is formed along with at least a portion of a poly-Si gate and/or gate connector(s) (which electrically connect multiple gates) of the active region. Such poly-Si devices may include, for example, sensors (such as current sensors or temperature sensors) or other polysilicon-based devices, including diodes, transistors (including bipolar and field effect transistors, such as IGBTs or FETs), thyristors, or other p-n junction-based devices, and are more generally referred to herein as integrated polysilicon devices. In some embodiments, the integrated polysilicon device(s), the gate connector(s), and/or the gates may be formed from respective portions of a continuous polysilicon layer, for example, an undoped polysilicon layer.

As such, power semiconductor devices in accordance with embodiments described herein may include integrated polysilicon devices including that may be free of or devoid of an inter-polysilicon dielectric layer (e.g., an IPO layer) that electrically isolates the integrated polysilicon devices from the gate connector; may have respective surfaces that are coplanar with a surface of the gate connector; and/or may be electrically connected by respective conductive vias that extend through an inter-metal dielectric (IMD) layer by a same depth as the conductive vias that provide electrical connection to the gate connector. The gate connectors may have a different conductivity (e.g., a different dopant concentration) than at least a portion of the gates, and/or may be formed from a same polysilicon layer as the integrated polysilicon devices and/or at least a portion of the gates.

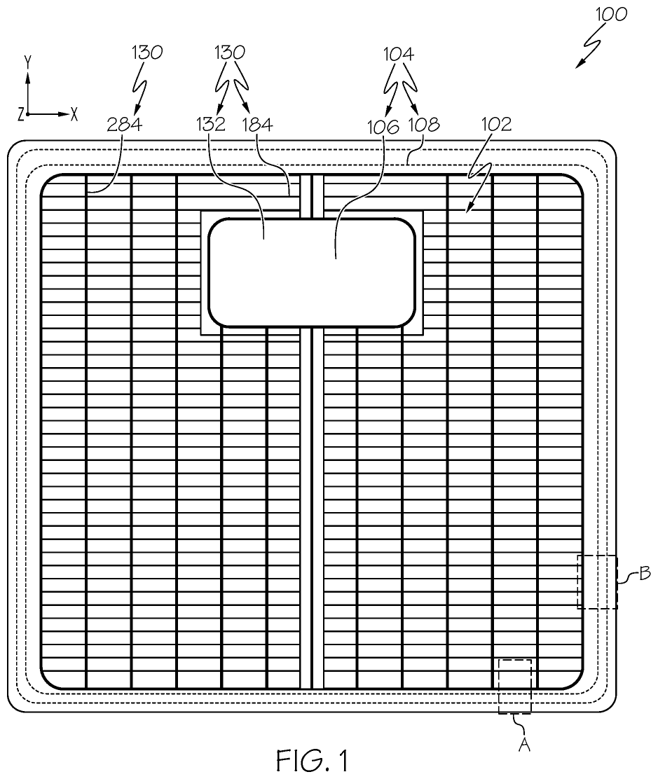

That is, in some embodiments of the present disclosure, integrated poly-Si devices can be formed without the use of IPO layers (for example, such that the gate connector and the integrated polysilicon devices may have coplanar upper and/or lower surfaces), and/or without the use of additional poly-Si deposition processes (for example, such that the gate connector and the integrated polysilicon devices may be formed from portions of a same polysilicon layer), thereby allowing for reduced cell pitch and/or greater efficiencies in fabrication. Specific examples of power semiconductor devices in accordance with embodiments described herein are provided below with reference to FIGS. 1 to 7.

FIG. 1 is a schematic plan view of a power semiconductor device 100 in accordance with some embodiments of the present disclosure. The illustrated power semiconductor device 100 may include a semiconductor structure having an active region 102 including p-n and/or Schottky junctions, which act as a main junction for blocking voltage in the reverse bias direction and providing current flow in the forward bias direction, and integrated devices adjacent the active region 102 (referred to herein as a peripheral region 104). The power semiconductor device 100 is illustrated as a trenched gate vertical power MOSFET by way of example only, but may be, for example, planar gate power MOSFETs, Schottky diodes, power IGBTs, or other power semiconductor devices. The power semiconductor device 100 has a “unit cell” structure in which the active region 102 includes a plurality of individual devices that are disposed in parallel to each other and that together function as a single power device.

Referring to FIG. 1, the power semiconductor device 100 includes a semiconductor structure 105 that includes an active region 102 and a peripheral region 104. The active region 102 is an area of the device that includes the unit cell transistors discussed herein, while the peripheral region 104 may include additional integrated semiconductor (e.g., polysilicon) devices that are not part of the active conduction area of the power switching device. It will be understood that the “peripheral region” may be, but is not necessarily, arranged along a perimeter of the device 100. That is, devices described herein as being formed on or in the peripheral region 104 may be outside the active region 102 (i.e., “peripheral” with respect to the main conduction path), but need not be along the edge or periphery of the device 100.

The active region 102 may generally correspond to the area under a source metal layer in some embodiments. The peripheral region 104 may include a gate pad portion 106 and an edge portion 108. The gate pad portion 106 may approximately correspond to the portion of the semiconductor structure that is underneath a gate bond pad. The edge portion 108 of the peripheral region 104 may extend around a periphery of the MOSFET 100 and may include one or more termination structures such as guard rings and/or a junction termination extension that can reduce electric field crowding that may occur around the edge of the device.

As is further shown in FIG. 1, a gate electrode structure 130 may be provided that includes a gate pad 132, a plurality of gate fingers (also referred to herein as gates) 184, and one or more gate buses that electrically connect the gates 184 to the gate pad 132. The gate pad 132 of the gate electrode structure 130 may be underneath the gate bond pad in the gate pad portion 106 of the peripheral region 104, and the gate fingers 184 may extend (e.g., horizontally) across the active region 102. An insulating layer (not shown) may cover the gate fingers 184 and gate bus(es) 136. The source metal layer may be provided over the gate fingers 184 and insulating layer, with the source contacts of the source metal layer contacting corresponding source regions in the semiconductor structure in openings between the gate fingers 184.

Still referring to FIG. 1, the gates 184 may distribute a gate signal of the device 100 throughout the active area 102. In some embodiments, the gates may extend in a common direction (e.g., the X direction in FIG. 1). In some embodiments, the gates 184 may include a conductive material (e.g., polysilicon or a silicide). In some embodiments, the gates 184 may be connected to a gate bus. Thus, a gate signal applied to the power switching device 100 may be communicated from the gate bond pad to the gate pad 132, to the gate bus, and then to the gate fingers 184. In general, the material utilized in the gate bus (which may be or contain, e.g., metal) may have a lower resistivity than that used in the gate fingers 184 (which may be or contain, e.g., polysilicon or silicide). The gate fingers 184 may be implemented in a trench gate configuration, in which a portion of the gate finger 184 extends below an upper surface of the semiconductor structure 105, and/or in a planar configuration, in which the gate finger 184 extends on an upper surface of the semiconductor structure 105.

The gate electrode structure 130 may further include one or more gate runners 284 (also referred to herein as gate connectors 284) that electrically interconnect the gate fingers 184. The gate connectors 284 may comprise a same conductive material (or may even be formed from portions of a same conductive layer) as one or more portions 184a, 184b of the gate fingers 184 (e.g., polysilicon or a silicide). As illustrated in FIG. 1, the gate connectors 284 may be incorporated into the power semiconductor device 100 to be on and/or contact one or more of the gate fingers 184. In some embodiments, the gate connectors 284 may extend in a second direction (e.g., a Y direction in FIG. 1) that intersects the first direction of the gate fingers 184. In some embodiments, the gate connectors 284 may extend in a same direction (e.g., the X-direction in FIG. 1) as the direction of extension of the gate fingers 184. The gate connectors 284 may be connected to one or more gate buses. For example, the gate connectors 284 may be connected to a gate bus at either end of the gate connector. In some embodiments, the gate connectors 284 may be electrically connected to the gate fingers 184 over which they traverse.

Though the gate connectors 284 are illustrated as extending from one side of the power semiconductor device 100 to the other, it will be recognized that the present embodiments are not limited thereto. In some embodiments, one or more of the gate connectors 284 may be connected to a gate bus and/or gate pad 132 at only one end of the gate connector 284. In addition, though the gate connectors 284 are illustrated as being distributed at regular intervals, the present embodiments are not limited thereto. In some embodiments, a density of the gate connectors 284 may vary in different locations on the power semiconductor device 100.

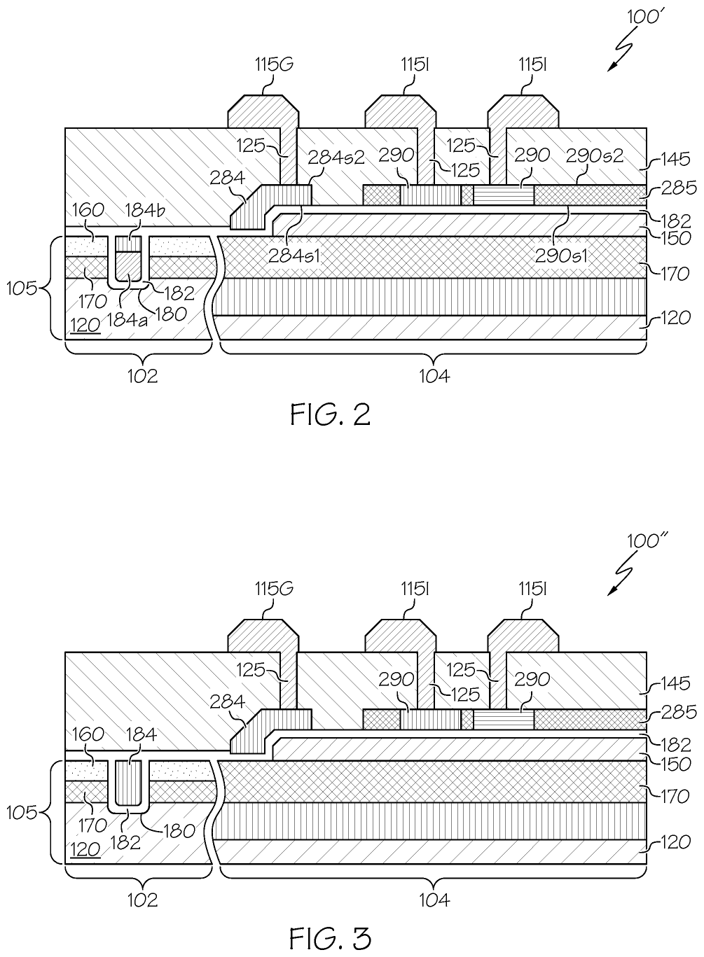

FIGS. 2 and 3 are schematic cross-sectional views illustrating example power semiconductor devices 100′ and 100″ taken along section ‘A’ of FIG. 1. Referring now to the cross-sectional views of FIGS. 2 and 3, the power semiconductor devices 100′ and 100″ (collectively, 100) each include a semiconductor structure 105. The semiconductor structure 105 includes a substrate (not shown) of a first conductivity type, for example, a heavily-doped (e.g., n⁺) substrate. A lightly-doped (e.g., n⁻) semiconductor drift layer or drift region 120 of the first conductivity type is provided on the substrate. In some embodiments, an upper portion of the drift region 120 may include a current spreading layer (“CSL”).

The semiconductor structure 105 may include wide band-gap semiconductor materials. In the example power semiconductor device 100, the substrate and the drift region 120 are silicon carbide (SiC)-based, for example, a SiC substrate and a SiC drift region 120 epitaxially grown thereon with a uniform or graded doping concentration. The substrate and the drift region 120 are not limited to SiC, and may be formed from other material systems, such as, for example, Group III nitrides (e.g., GaN), gallium arsenide (GaAs), silicon (Si), germanium (Ge), silicon germanium (SiGe), and the like.

Moderately-doped regions of a second, opposite conductivity type (e.g., p) may be formed (for example, by epitaxial growth or implantation) on the drift region 120, and may act as the well regions or wells 170 (e.g., p-type wells or “p-wells”) for the device 100. Heavily-doped (e.g., n⁺) regions 160 may be formed in upper portions of the wells 170. The heavily-doped regions 160 may act as source regions for the unit cell transistors. In some embodiments, the wells 170 and the source regions 160 may be formed via ion implantation in the drift region 120. In some embodiments, the wells 170 may be formed of a layer deposited on the upper surface of the drift region 120, into which the source regions 160 are implanted. Source contacts may be formed on the heavily-doped source regions 160. The source contacts may be ohmic metal in some embodiments. The drift region 120 and the substrate together act as a common drain region for the unit cell transistors. A drain contact may be formed on the lower surface of the substrate, for example, opposite the drift region 120. While the power semiconductor devices 100′, 100″ are illustrated as n-type devices, it will be appreciated that in p-type devices the above conductivity types and source and drain contact locations are reversed.

Gate trenches 180 may be formed in the drift region 120 in the active region 102. In some embodiments, a bottom surface of the gate trench 180 may extend into the drift region 120 beyond a lower boundary of the wells 170. A gate insulating layer 282 may be formed on the sidewalls and floor of each gate trench 180. The gate insulating layer 282 may include, for example, a silicon dioxide (SiO₂) layer, although other insulating materials, such as SiOₓN_{y}, SiₓN_{y}, Al₂O₃ and/or high-K dielectrics such as hafnium oxide, and the like may be used.

A gate electrode 184 (also referred to herein as a gate 184) may be formed in each gate trench 180 on the gate insulating layer 182. The gate electrode 184 may include, for example, a silicide, doped polycrystalline silicon (referred to herein as polysilicon or poly-Si). The gate insulating layer 182 and/or gate electrode 184 may be formed within the trenches 180 in the drift region 120 between the wells 170 and source regions 160 and, in some embodiments, may extend onto the surface of the drift region 120 outside the trenches 180. In some embodiments, a portion of an upper surface of the gate insulating layer 182 and a portion of an upper surface of the gate electrode 184 may be coplanar with an upper surface the drift region 120 outside the trenches 180 (e.g., an upper surface of the source regions 160), though the embodiments described herein are not limited thereto. It will be appreciated that the gate electrode 184 may be a gate finger 184 of the continuous gate electrode structure 130 (see FIG. 1).

Transistor conduction channels are provided in the well regions 170 adjacent the gate insulating layer 182, along opposing sidewalls of each gate trench 180. In particular, application of a bias voltage to the gate electrode 184 forms a vertical conduction channel that extends through the portion of the 170 that are underneath the source regions 160. A gate contact may be formed on each gate electrode 184. The source, drain, and gate contacts are not shown for ease of illustration.

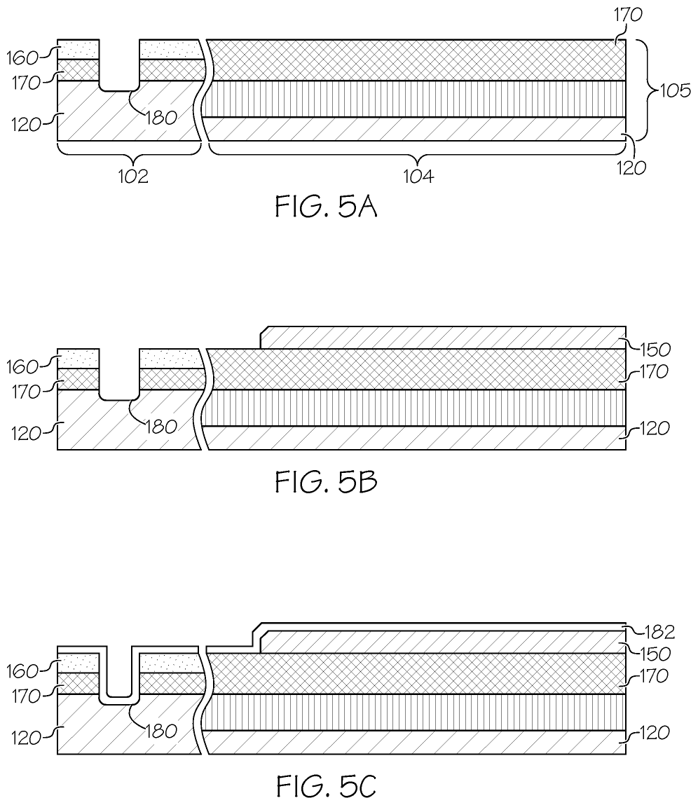

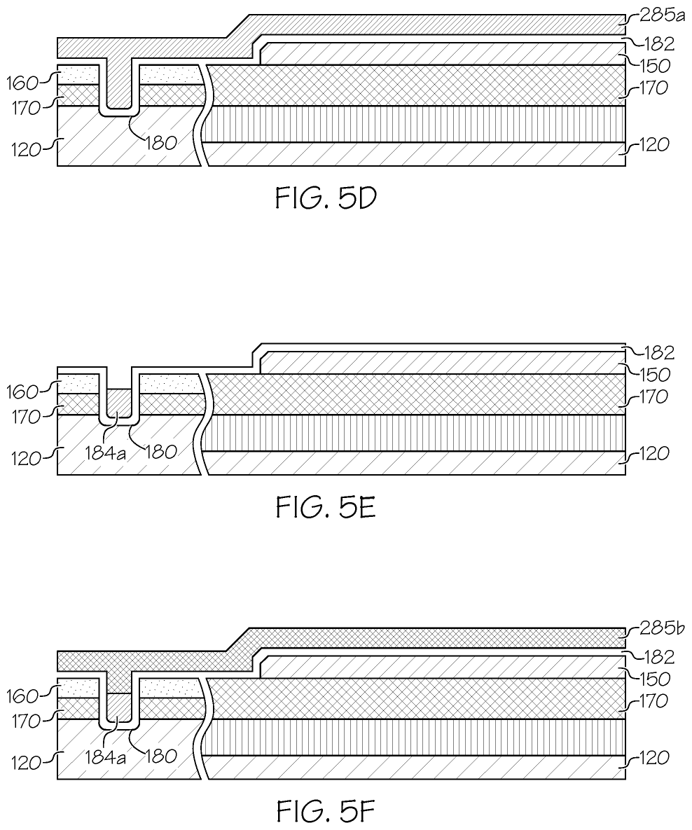

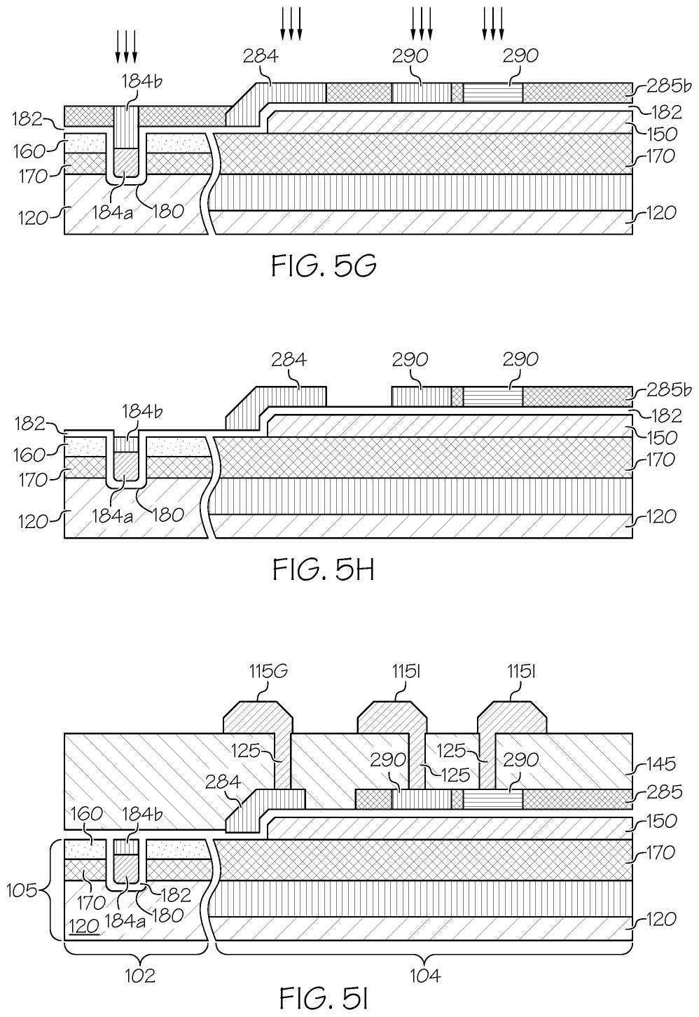

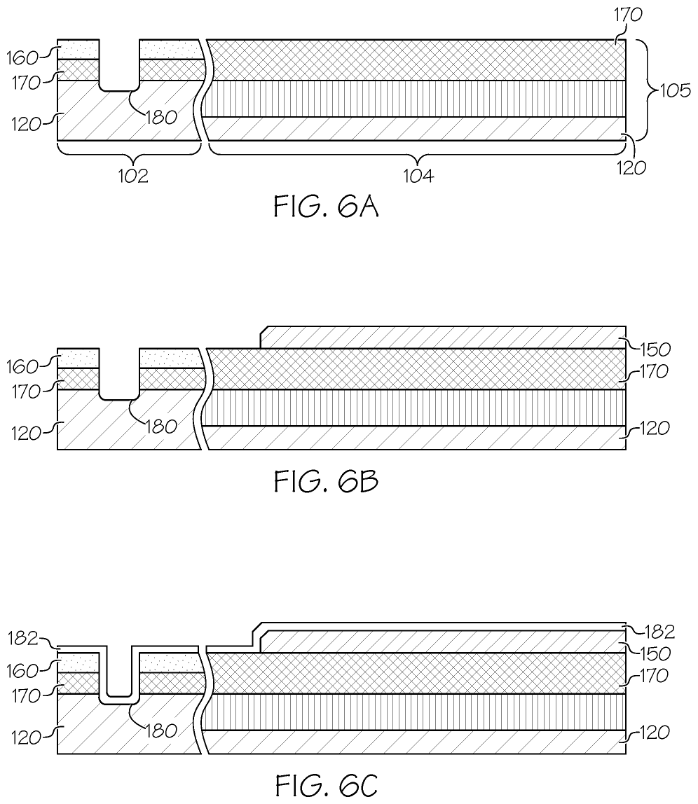

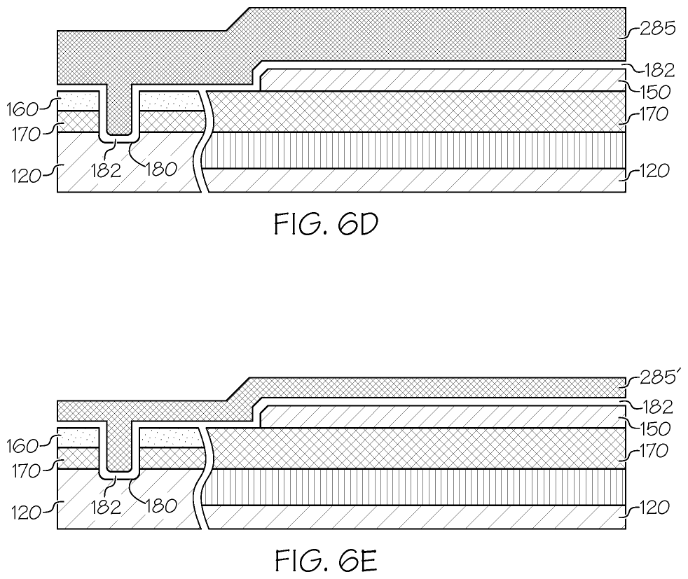

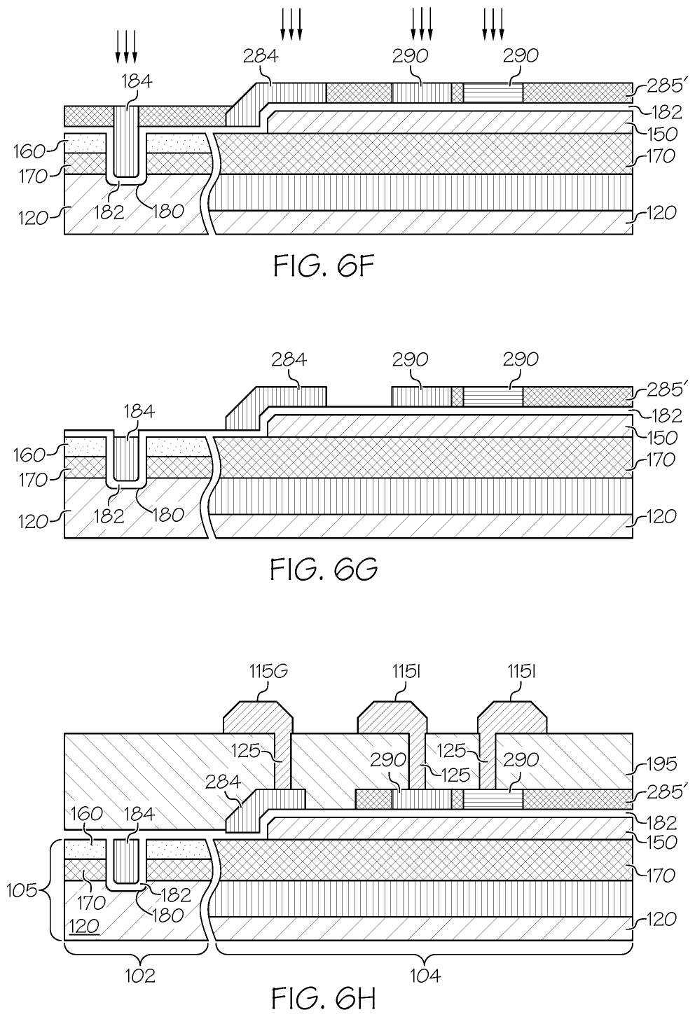

A plurality of gate connectors 284 may electrically connect the gates 184. For example, the gate 184 may extend in an X-direction and the gate connectors 284 may extend in the Y-direction. The gate connectors 284 may be arranged to periodically be on and/or directly contact the gate fingers 184. The gate connectors 284 may extend on and/or directly contact adjacent ones of the gate fingers 184 and a given gate electrode 184 may be connected to and/or contact more than one gate connector 284. The gate connectors 284 may comprise a same conductive material as at least a portion of the gates 184. For example, polysilicon or silicide may be used as the material of the gates 184, for example, due to processing operations that utilize high temperatures after the gates 184 are formed. Also, since silicon is chemically inert at the interface with the gate insulating layer 182, it may be utilized as part of the gates 184 to form higher quality gate electrodes. However, polysilicon may have a higher resistance than other metals. As such, the polysilicon gates 184 and/or the gate connectors 284 may be doped or otherwise processed so as to increase conductivity/reduce resistance. In some embodiments (e.g. as shown in FIGS. 5A-5I), the gate connectors 284 may have a different conductivity (e.g., a different polarity and/or a different dopant concentration) than at least a portion of the gates 184. In some embodiments (e.g., as shown in FIGS. 6A-6H), the gate connectors 284 may have a same conductivity than at least a portion of the gates 184.

As shown in FIGS. 2 and 3, at least one integrated polysilicon device 290 is provided in or on the semiconductor structure 105 adjacent the active region 102. One or more of the gate connectors 284 may be provided in or on the semiconductor structure 105 between (i.e., in a lateral direction, such in as the X- or Y-direction; shown as the Y-direction) the integrated polysilicon device(s) 290 and the gates 184. The integrated polysilicon device(s) 290 are electrically isolated from the gate connector 284 free of or devoid of an inter-polysilicon dielectric layer 195 therebetween. As described herein an inter-polysilicon dielectric layer (e.g. an IPO) may refer to a dielectric layer that extends between two or more polysilicon layers. The inter-polysilicon dielectric layer may include, for example, oxide, nitride, oxynitride, high-K dielectric, or other dielectric materials, and may have a thickness of about 0.01 μm to about 10 μm.

Still referring to FIGS. 2 and 3, one or more insulating layers 145 may electrically isolate and physically separate the gate connector 284 and the integrated polysilicon devices 290 from a top surface of the device 100. For example, an inter-metal dielectric (IMD) layer 145 may be provided on the gate connector 284 and the integrated polysilicon device(s) 290, between the gate connector 284 and top surface of the device. In contrast to an IPO layer, the inter-metal dielectric layer 145 may extend between a metal layer (e.g., metal contacts 115G, 115I) and one or more underlying or overlying layers. The inter-metal dielectric layer 145 may include, for example, oxide, nitride, oxynitride, high-K dielectric, or other dielectric materials, such one or more silicon dioxide (SiO₂) layers. Other examples of the inter-metal dielectric layer 145 may include SiOₓN_{y}, SiₓN_{y}, Al₂O₃ and/or high-K dielectrics such as hafnium oxide. In some embodiments, the inter-metal dielectric layer 145 may physically contact portions of the gate insulating layer 182 extending on the surface of the drift region. The thickness of the inter-metal dielectric layer 145 may be between 0.01 μm nm to 10 μm. In some embodiments, the inter-metal dielectric layer 145 may include a same material as the gate insulating layer 182 and/or may include additional dielectrics formed either before or after the gate insulating layer 182. Respective conductive vias 125 extend through the inter-metal dielectric layer 145 to electrically contact the gate connectors 284 and the at least one integrated polysilicon device 290.

The integrated polysilicon devices 290 and portions of the gate connector 284 may also be insulated from the underlying drift region 120 of the semiconductor structure 105. For example, an isolation layer 150 (e.g. a field oxide layer) may be provided on the semiconductor structure 105 between the plurality of gates and the integrated polysilicon device(s) 290, and the integrated polysilicon device(s) 290 may be provided on the isolation layer free of the inter-polysilicon dielectric layer therebetween. The isolation layer 150, may include, for example, oxide, nitride, oxynitride, high-K dielectric, or other dielectric materials, and may have a thickness of about 0.01 μm to about 10 μm.

In contrast with some conventional device structures 10 as shown in FIG. 8A, the integrated polysilicon device(s) 290 may be free of overlap with the gate connector 284 in a direction perpendicular to the semiconductor structure 105. In some embodiments, the integrated polysilicon device(s) 290 and the gate connectors 284 may be portions of a same polysilicon layer 285. As such, the integrated polysilicon device(s) 290 may include a surface that is coplanar with a surface of the gate connectors 284. For example, the integrated polysilicon device(s) 290 may include upper or lower surfaces 290s2, 290s1 that are coplanar with upper or lower surfaces 284s2, 284s1 of the gate connectors 284. Also, the respective conductive vias 125 may extend through the inter-metal dielectric layer 145 by a same depth to electrically contact the gate connector 284 and the integrated polysilicon devices 290. Thus, as shown in the example devices 100′ and 100″ of FIGS. 2 and 3, embodiments of the present disclosure may not include an IPO layer, and may not require additional undoped polysilicon deposition processes (other than or beyond forming the polysilicon layer 285 from which the gate connectors 284 are formed).

In the example device 100′ shown in FIG. 2, the gates 184 respectively include first and second portions 184a and 184b, and the gate connectors 284 have a different conductivity than the first portions 184a of the gates 184. For example, the first portions 184a of the gates 184 may include a greater dopant concentration than the second portions 184b. The gate connectors 284 may include a same dopant concentration as the second portions 184b of the gates 184. The example device 100′ of FIG. 2 may be formed by the fabrication processes described below with reference to FIGS. 5A-5I.

In the example device 100″ shown in FIG. 3, the gates 184 and the gate connectors 284 have a same conductivity. For example, the gates 184 may include a same dopant concentration as the gate connectors 284. The example device 100″ of FIG. 3 may be formed by the fabrication processes described below with reference to FIGS. 6A-6H. In the devices 100′ and 100″ of FIGS. 2 and 3, the integrated polysilicon device(s) 290 may have a same conductivity as or a different conductivity than the gate connectors 284.

While illustrated in FIGS. 2 and 3 with gates 184 that extend in respective gate trenches 180 in the semiconductor structure 105, and with the integrated polysilicon devices 290 including planar surfaces 290s1, 290s2 on the semiconductor structure 105 adjacent the active region 102, it will be understood that embodiments of the present disclosure are not limited to trench gate and planar integrated polysilicon device configurations. For example, in some embodiments, the integrated polysilicon devices 290 may extend in respective trenches in the semiconductor structure 105 adjacent the active region 102, that is, such that both the gates 184 and the integrated polysilicon devices 290 have trench configurations. In further embodiments the plurality of gates 184 may include respective planar surfaces 184s on the semiconductor structure 105, while the integrated polysilicon devices 290 may extend in respective trenches in the semiconductor structure 105 adjacent the active region 102.

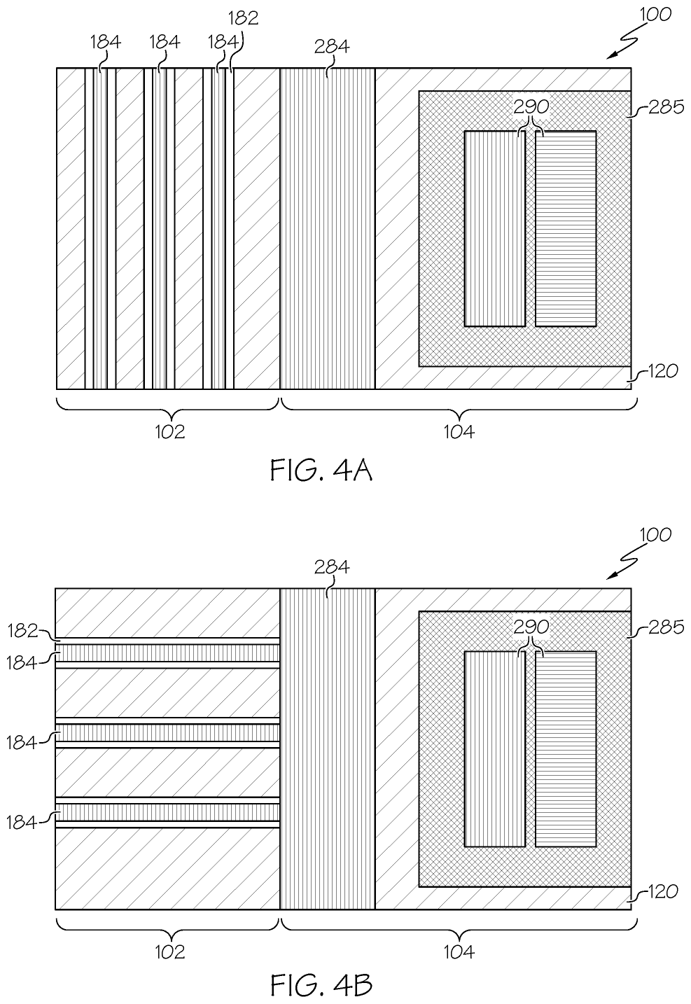

FIGS. 4A and 4B are schematic plan views illustrating example power semiconductor devices according to some embodiments of the present disclosure. More particularly, the plan view of FIG. 4A illustrates that the gate connector 284 may extend along a same direction (e.g., the X-direction) as the gate trenches 180 and the gates 184 therein. For example, FIG. 4A may be an enlarged view of section ‘A’ shown in the plan view of FIG. 1. The plan view of FIG. 4B, in contrast, illustrates that the gate connector 284 may extend along a different direction (e.g., the Y-direction), which may be perpendicular to or may otherwise intersect the direction (e.g., the X-direction) of extension of the gate trenches 180 and the gates 184. For example, FIG. 4B may be an enlarged view of section ‘B’ shown in the plan view of FIG. 1. More generally, it will be understood that the gate connectors 284 and the gates 184 may extend in any directions that allow for electrical connection therebetween, and are not limited the specific directions of extension described and illustrated herein.

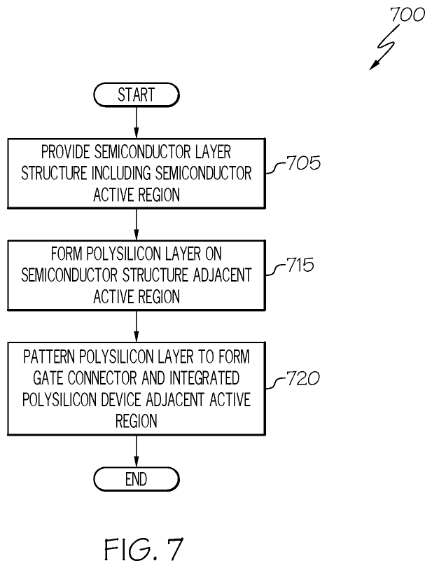

Methods of fabricating power semiconductor devices in accordance with some embodiments are described below with reference to the schematic cross-sectional views shown in FIGS. 5A-5I, FIGS. 6A-6H, and the flowchart of FIG. 7. In these examples, only the drift layer (and portions thereof) are shown for ease of illustration, but it will be understood that the illustrated semiconductor layer structures may include a substrate and additional semiconductor layers of a first conductivity type that are provided on the substrate, e.g., by epitaxial growth. The semiconductor structure may include wide band-gap semiconductor materials, including but not limited to SiC substrates and SiC drift layers that are epitaxially grown thereon with a uniform or graded doping concentration.

FIGS. 5A-5I illustrate example methods of fabricating a power semiconductor device 100′ in accordance with the cross-sectional view shown in FIG. 2. Referring now to FIGS. 5A and 7, a method of fabricating a power semiconductor device 100′ includes providing a semiconductor structure 105 including a first region (e.g., an active region 102 in which transistors are formed to provide the active conduction area of the power semiconductor device) and a second region (e.g., a peripheral region 104 in which one or more integrated polysilicon devices are formed) at block 705. For example, a lightly-doped (e.g., n−) semiconductor drift region 120 of a first conductivity type may be formed on a semiconductor substrate via epitaxial growth. A current spreading layer of the first conductivity type may be formed in the upper portion of the drift region 120.

The drift region 120 includes the active region 102 and the adjacent peripheral region 104. Well regions 170 may be formed in or on the drift region 120, for example using one or more masking and ion implantation processes. The well regions 170 may be formed in both the active region 102 and the adjacent peripheral region 104. Heavily-doped (e.g., n⁺) source regions 160 are formed in upper portions of the active region 102, for example, via masking and ion implantation. Respective gate trenches 180 are formed extending in a first (e.g. X−) direction in the active region 102, for example, by one or more masking and etching processes.

Referring now to FIG. 5B, a device isolation layer 150 (e.g., a field oxide layer) is selectively formed on a surface of the semiconductor structure 105 in the peripheral region 104. As shown in FIG. 5C, a gate insulating layer 182 (e.g., gate oxide layer) is formed in the gate trenches 180. For example, the gate insulating layer 182 may be conformally formed in the gate trenches 180, on surfaces of the active region 102 outside the gate trenches 180, and on a surface of the peripheral region 104 and the device isolation layer 150.

Referring now to FIG. 5D, a polysilicon layer (in this example, a first polysilicon layer 285a) is formed on the semiconductor structure adjacent to the active region 102 (e.g., on at least the surface of the peripheral region 104). For example, the first polysilicon layer 285a may be a heavily doped polysilicon layer that is blanket deposited on the surface of the peripheral region 104 and the surface of the active region 102, and may extend into the gate trenches 180. As shown in FIG. 5E, the first polysilicon layer 285a may be patterned (e.g., by a thinning process) to substantially remove the first polysilicon layer 285a from the surfaces of the active region 102 and the peripheral region 104. As such, a portion 184a of the first polysilicon layer 285a may remain in the gate trenches 180, thereby forming first portions 184a of the gate electrodes 184.

Referring now to FIG. 5F and FIG. 7, a polysilicon layer 285b (in this example, a second polysilicon layer 285b) is formed on the semiconductor structure 105 adjacent the active region 102 (e.g., on at least the surface of the peripheral region 104) at block 715. For example, the second polysilicon layer 285b may be undoped polysilicon, and may be blanket deposited on the surface of the peripheral region 104 and the surface of the active region 102, and may extend into the gate trenches 180 and on the first portions 184a of the gate electrodes 184. As shown in FIG. 5G, portions of the second polysilicon layer 285a are selectively doped (e.g., by performing one or more masking and ion implantation processes to implant dopants into one or more portions of the polysilicon layer 285b) to provide respective regions of the first conductivity type (e.g., n-type) or the second conductivity type (e.g., p-type) therein. In some embodiments, the implantation process or other selective doping process may be performed such that portions of the second polysilicon layer 285b that extend into the gate trenches 180 in the active region may have a different conductivity (e.g., a different dopant concentration and/or a different polarity/conductivity type) than the first portions 184a of the gate electrodes 184 in the gate trenches 180.

Referring now to FIG. 5H and FIG. 7, the polysilicon layer 285b is patterned to form a gate connector 284 and at least one integrated polysilicon device 290 in or on the semiconductor structure 105 adjacent the active region 102 at block 720. For example, the patterning process may include selectively removing portions of the second polysilicon layer 285b such that the selectively doped regions of the second polysilicon layer 285b remain, so as to simultaneously form the gate connector 284 and the integrated polysilicon device(s) 290 in the peripheral region 104, and to form second portions 184b of the gates 184 in the gate trenches 180 in the active region 102. The gates 184 may thereby be formed with first portions 184a and second portions 184b having different conductivities. For example, the first portions 184a of the gates 180 (which were formed by patterning doped polysilicon layer 285a) may have a greater dopant concentration and/or different polarity than the second portions 184b of the gates 184 (which were formed by selective doping of the second polysilicon layer 285b). The gate connector 284 may be formed to have a same conductivity as the second portions 184b of the gates 184, but may have a different conductivity than the first portions 184a of the gates.

By performing the patterning process shown in FIG. 5H, the integrated polysilicon device(s) 290 and the gate connector 284 may thereby be formed from respective portions of the same polysilicon layer 285b (which in this example also forms the second portions 184b of the gates 184). As such, the gate connector 284 and the integrated polysilicon device(s) 290 may have respective coplanar surfaces. For example, the integrated polysilicon device(s) 290 and at least a portion of the gate connector 284 may extend on the surface of the device isolation layer 150 in the peripheral region of the semiconductor structure 105, such that respective lower surfaces 290s1 and 284s1 are substantially coplanar.

As shown in FIG. 5I, an inter-metal dielectric layer 145 may be formed on the integrated polysilicon device(s) 290 and the gate connector 284. For example, inter-metal dielectric layer 145 may be formed on the semiconductor structure 105, on both the active region 102 and the peripheral region 104. Respective conductive vias 125 may be formed extending through the inter-metal dielectric layer 145, and respective contacts 115G, 115I may be formed on a surface of the inter-metal dielectric layer 145 to provide electrical connections to the gate connector 284 and the integrated polysilicon device(s) 290. The surface of the inter-metal dielectric layer 145 having the respective contacts 115G, 115I thereon may be substantially planar. The respective contacts 115G, 115I may be portions of one or more metal layers formed on the inter-metal dielectric layer 145.

As shown in the fabrication operations of FIGS. 5A-5I, the integrated polysilicon device(s) 290 and the gate connector 284 may the electrically isolated from one another free of an inter-polysilicon dielectric layer (e.g., an IPO layer 95) therebetween. For example, by forming the gate connector 284 and the integrated polysilicon device(s) 290 from respective portions of the same polysilicon layer 285b, the gate connector 284 and the integrated polysilicon device(s) 290 may be free of overlap with one another in a direction perpendicular to the semiconductor structure 105, thereby providing electrical isolation between the integrated polysilicon device 290 and the gate connector 284 without the use of IPO layers 95. In some embodiments, the structure of the power semiconductor device 100 may be devoid of inter-polysilicon dielectric layers.

Also, the respective conductive vias 125 may extend through the inter-metal dielectric layer 145 by a same distance or depth (relative to a surface of the IMD layer 145) to electrically contact the gate connector 284 and the integrated polysilicon device(s) 290. For example, by forming the gate connector 284 and the integrated polysilicon device(s) 290 from respective portions of the same polysilicon layer 285b, the gate connector 284 and the integrated polysilicon device(s) 290 may have respective coplanar upper surfaces 284s2 and 290s2), such that conductive vias 125 of the same thickness may be used to provide electrical contact to the gate connector 284 and the integrated polysilicon device(s) 290.

In addition, the gate connector 284 in the peripheral region 104 may have a different conductivity than the first portions 184a of the gates 184 in the active region 102, but may have a same conductivity as the second portions 184b of the gates 184. For example, by forming the first portions 184a of the gates 184 from a first (e.g., heavily-doped) polysilicon layer 285a, and forming the second portions 184b of the gates 184 and the gate connector 284 from a second (e.g., undoped) polysilicon layer 285b, the gate connector 284 may have a same dopant concentration as the second portions 184b of the gates 184, but may have a different or lower dopant concentration than the first portions 184a of the gates 184.

FIGS. 6A-6H illustrate example methods of fabricating a power semiconductor device 100″ in accordance with the cross-sectional view shown in FIG. 3. Referring now to FIGS. 6A and 7, a method of fabricating a power semiconductor device 100″ includes providing a semiconductor structure 105 including a first region (e.g., an active region 102) and a second region (e.g., a peripheral region 104) at block 705. Respective gate trenches 180 are formed extending in a first (e.g. X−) direction in the active region 102, for example, by one or more masking and etching processes. In FIG. 6B, a device isolation layer 150 (e.g., a field oxide layer) is selectively formed in the peripheral region 104. As shown in FIG. 6C, a gate insulating layer 182 (e.g., gate oxide layer) is formed in the gate trenches 180.

Referring now to FIG. 6D and FIG. 7, a polysilicon layer 285 (in this example, an undoped polysilicon layer 285) is formed on the semiconductor structure adjacent to the active region 102 (e.g., on at least the surface of the peripheral region 104) at block 715. For example, the polysilicon layer 285 may be undoped polysilicon, and may be blanket deposited on the surface of the peripheral region 104 and the surface of the active region 102, and may extend into the gate trenches 180. As shown in FIG. 6E, the first polysilicon layer 285 may be patterned (e.g., by a thinning process) to substantially reduce a thickness thereof, providing a thinned polysilicon layer 285′ that extends (e.g., continuously) on the surfaces of the active region 102 and the adjacent peripheral region 104, with portions thereof extending into the gate trenches 180.

Referring now to FIG. 6F, portions of the polysilicon layer 285′ are selectively doped (e.g., by performing one or more masking and ion implantation processes to implant dopants into one or more portions of the polysilicon layer 285′) to provide respective regions of the first conductivity type (e.g., n-type) or the second conductivity type (e.g., p-type) therein. The implantation process or other selective doping process may be performed such that portions of the polysilicon layer 285 that extend into the gate trenches 180 in the active region 102 (i.e., the portions from which the gates 184 may be formed) may have a same conductivity (e.g., a same dopant concentration and/or a same polarity/conductivity type) as the portions of the polysilicon layer 285 that extend on the peripheral region 104 (i.e., the portions from which the gate connectors 284 may be formed).

Referring now to FIG. 6G and FIG. 7, the polysilicon layer 285′ is patterned to form a gate connector 284 and at least one integrated polysilicon device 290 in or on the semiconductor structure 105 adjacent the active region 102 at block 720. For example, the patterning process may include selectively removing undoped portions of the polysilicon layer 285′ such that the selectively doped regions remain, so as to simultaneously form the gate connectors 284 and the integrated polysilicon device(s) 290 in the peripheral region 104 and the gates 184 in the gate trenches 180 in the active region 102.

By performing the patterning process shown in FIG. 6G, the integrated polysilicon device(s) 290 and the gate connectors 284 may thereby be formed from respective portions of the same polysilicon layer 285′ (which in this example also forms the gates 184). As such, the gate connector 284 and the integrated polysilicon device(s) 290 may have respective coplanar surfaces. For example, as in the embodiments of FIGS. 5A-5I, the integrated polysilicon device(s) 290 and at least a portion of the gate connector 284 may extend on the surface of the device isolation layer 150 in the peripheral region of the semiconductor structure 105, such that their respective lower surfaces 290s1 and 284s1 are substantially coplanar. In contrast to the embodiments of FIGS. 5A-5I, the gate connector 284 may be formed to have a same conductivity (e.g., a same or similar dopant concentration) as the gates 184.

As shown in FIG. 6H, an inter-metal dielectric layer 145 may be formed on the integrated polysilicon device(s) 290 and the gate connector 284, respective conductive vias 125 may be formed to extend through the inter-metal dielectric layer 145, and respective contacts 115G, 115I may be formed on a surface of the inter-metal dielectric layer 145 (e.g., from portions of one or more metal layers formed thereon) to provide electrical connections to the gate connector 284 and the integrated polysilicon device(s) 290.

In the fabrication operations of FIGS. 6A-6H, the integrated polysilicon device(s) 290 and the gate connectors 284 may the electrically isolated from one another free of an inter-polysilicon dielectric layer (e.g., an IPO layer 95) therebetween. For example, by forming the gate connectors 284 and the integrated polysilicon device(s) 290 from respective portions of the same polysilicon layer 285′, the gate connectors 284 and the integrated polysilicon device(s) 290 may be free of overlap with one another in a direction perpendicular to the semiconductor structure 105, thereby providing electrical isolation between the integrated polysilicon device 290 and the gate connectors 284 without the use of IPO layers 95. In some embodiments, the structure of the power semiconductor device 100″ may be devoid of inter-polysilicon dielectric layers. Also, the gate connectors 284 and the integrated polysilicon device(s) 290 may have respective coplanar upper surfaces 284s2 and 290s2, and the respective conductive vias 125 may extend through the inter-metal dielectric layer 145 by a same distance or depth (relative to a surface of the IMD layer 145) to electrically contact the gate connectors 284 and the integrated polysilicon device(s) 290.

Referring to FIGS. 5A-5I and FIGS. 6A-6H, additional operations may be performed to provide device contacts may be formed on the top and bottom surfaces of the semiconductor structure 105. For example, a drain contact may be formed on the lower surface of the substrate 110 opposite the drift region 120. Source contacts may be formed at the upper portion of the semiconductor structure on the heavily-doped source region 160. The source contacts may be ohmic metal in some embodiments, and may provide electrical connection to shielding patterns (not shown) which may extend along a bottom surface and/or sidewall of the gate trenches 180 in some embodiments. For example, the source contacts may provide a common source that is configured to electrically connect the shielding patterns to an electrical ground.

While the fabrication steps are set forth in example orders or sequences in the discussion above, it will be appreciated that the fabrication steps may be performed in a different order. For example, the order of the various etching and ion implantation steps may be changed from what is described above. More generally, while illustrated herein with reference to fabricating power semiconductor devices using particular sequences of operations, it will be understood that one or more of the operations may be performed out of the sequences or order shown.

Also, while primarily illustrated herein with reference to trenched vertical semiconductor power transistors or other power devices requiring an implanted trench region in combination with planar integrated semiconductor devices, it will be understood that integrated polysilicon devices may have a trenched device structure in some embodiments. For example, power semiconductor devices including trenched gate transistors and trenched integrated polysilicon devices may allow for reduction in cell pitch. Conversely, the power transistor devices may have a planar gate device structure (rather than the illustrated trenched gate devices), while the integrated polysilicon devices may have a trenched device structure. That is, in embodiments described herein, at least one of the gates or the integrated polysilicon devices may be provided in trenches in the semiconductor structure. More generally, embodiments of the present invention may include any combination of the above and/or other operations to provide integrated polysilicon devices (trenched or planar) that are electrically isolated from a conductive connector or runner that electrically connects unit cells of a power semiconductor device without the use of inter-polysilicon dielectric layers, and/or without the use of additional polysilicon deposition processes.

Also, while the present disclosure is described herein primarily with respect to power MOSFET implementations, it will be appreciated that the techniques described herein apply equally well to other power semiconductor devices that may include junction or edge termination regions. That is, embodiments of the present disclosure are not limited MOSFETs, and the techniques disclosed herein may be used in other power semiconductor devices, such as IGBTs, Schottky diodes, or any other appropriate device.

It will be appreciated that features of the different embodiments disclosed herein may be combined in any way to provide many additional embodiments. For example, features of any MOSFET embodiment described herein may be incorporated into IGBT embodiments fabricated on SiC, or other semiconductor materials such as Si. Thus, it will be appreciated that various features of the inventive concepts are described herein with respect to specific examples, but that these features may be added to other embodiments and/or used in place of example features of other embodiments to provide many additional embodiments. The present disclosure should therefore be understood to encompass these different combinations.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure (e.g., MOSFET, IGBT, etc.).

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

The present disclosure has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above. It will also be appreciated that the different features of the different embodiments described herein may be combined to provide additional embodiments.

Embodiments of the present disclosure have been described above with reference to the accompanying drawings, in which embodiments of the invention are shown. It will be appreciated, however, that this invention may be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

It will be understood that, although the terms first, second, etc., are used throughout this specification to describe various elements, these elements should not be limited by these terms. These terms are only used to distinguish one element from another. For example, a first element could be termed a second element, and, similarly, a second element could be termed a first element, without departing from the scope of the present disclosure. The term “and/or” includes any and all combinations of one or more of the associated listed items.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to flow charts. It will be appreciated that the steps shown in the flow charts need not be performed in the order shown.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a semiconductor structure comprising an active region;
a plurality of gates that extend in a first direction in or on the active region of the semiconductor structure;
at least one integrated polysilicon device in or on a surface of the semiconductor structure adjacent the active region; and
a gate connector electrically connecting the plurality of gates, wherein the gate connector is in or on the surface of the semiconductor structure between the at least one integrated polysilicon device and the plurality of gates,
wherein the at least one integrated polysilicon device is electrically isolated from the gate connector devoid of an inter-polysilicon dielectric layer therebetween.

2. The power semiconductor device of claim 1, wherein the at least one integrated polysilicon device does not overlap with the gate connector in a direction perpendicular to the surface of the semiconductor structure.

3. The power semiconductor device of claim 1, wherein the at least one integrated polysilicon device comprises a surface that is coplanar with a surface of the gate connector.

4. The power semiconductor device of claim 1, wherein the at least one integrated polysilicon device and the gate connector comprise portions of a same polysilicon layer.

5. The power semiconductor device of claim 1, further comprising:
an isolation layer on the surface of the semiconductor structure, wherein the at least one integrated polysilicon device is on the isolation layer devoid of the inter-polysilicon dielectric layer therebetween.

6. The power semiconductor device of claim 1, further comprising:
an inter-metal dielectric layer on the gate connector and the at least one integrated polysilicon device; and
respective conductive vias that extend through the inter-metal dielectric layer by a same depth to electrically contact the gate connector and the at least one integrated polysilicon device.

7. The power semiconductor device of claim 1, wherein the plurality of gates respectively comprise first and second portions that extend in a first direction in respective gate trenches in the active region, and the gate connector has a different conductivity than the first portions.

8. The power semiconductor device of claim 7, wherein the first portions of the plurality of gates comprise a greater dopant concentration than the second portions, and the gate connector comprises a same dopant concentration as the second portions of the plurality of gates.

9. The power semiconductor device of claim 1, wherein the plurality of gates extend in respective gate trenches in the active region, and wherein the at least one integrated polysilicon device extends in a trench in the semiconductor structure adjacent the active region.

10. The power semiconductor device of claim 1, wherein the plurality of gates extend in respective gate trenches in the active region, and wherein the at least one integrated polysilicon device comprises a planar surface on the surface of the semiconductor structure adjacent the active region.

11. The power semiconductor device of claim 1, wherein the plurality of gates comprise respective planar surfaces on the active region, and wherein the at least one integrated polysilicon device extends in a trench in the semiconductor structure adjacent the active region.

12. A power semiconductor device, comprising:
a semiconductor structure comprising an active region;
a plurality of gates that extend in a first direction in or on the active region of the semiconductor structure;
a gate connector electrically connecting the plurality of gates; and
at least one integrated polysilicon device in or on the semiconductor structure adjacent the gate connector, wherein the at least one integrated polysilicon device and the gate connector comprise respective surfaces that are coplanar.

13. The power semiconductor device of claim 12, wherein the respective surfaces of the at least one integrated polysilicon device and the gate connector comprise portions of a same polysilicon layer.

14. The power semiconductor device of claim 12, wherein the at least one integrated polysilicon device is electrically isolated from the gate connector devoid of an inter-polysilicon dielectric layer therebetween.

15.-17. (canceled)

18. A power semiconductor device, comprising:
a semiconductor structure comprising an active region;
a plurality of gates that extend in a first direction in or on the active region of the semiconductor structure;
a gate connector electrically connecting the plurality of gates;
at least one integrated polysilicon device in or on the semiconductor structure adjacent the gate connector;
an inter-metal dielectric layer on the gate connector and the at least one integrated polysilicon device; and
respective conductive vias that extend through the inter-metal dielectric layer by a same depth to electrically contact the gate connector and the at least one integrated polysilicon device.

19. The power semiconductor device of claim 18, wherein the at least one integrated polysilicon device comprises a surface that is coplanar with a surface of the gate connector.

20. The power semiconductor device of claim 19, further comprising respective contacts on a surface of the inter-metal dielectric layer opposite the semiconductor structure and electrically connected to the respective conductive vias, wherein the surface of the inter-metal dielectric layer is substantially planar.

21. The power semiconductor device of claim 18, wherein the at least one integrated polysilicon device and the gate connector comprise portions of a same polysilicon layer.

22. The power semiconductor device of claim 18, wherein the at least one integrated polysilicon device is electrically isolated from the gate connector devoid of an inter-polysilicon dielectric layer therebetween.

23.-24. (canceled)

25. A power semiconductor device, comprising:
a semiconductor structure comprising an active region;
a plurality of gates that extend in a first direction in respective trenches in the active region of the semiconductor structure;
at least one integrated polysilicon device in or on the semiconductor structure adjacent the plurality of gates; and
a gate connector electrically connecting the plurality of gates, wherein the gate connector is in or on the semiconductor structure between the at least one integrated polysilicon device and the plurality of gates,
wherein the plurality of gates respectively comprise first and second portions in the respective trenches, and the gate connector has a different conductivity than the first portions.

26. The power semiconductor device of claim 25, wherein the first portions of the gates have a greater conductivity than the second portions of the gates.

27. The power semiconductor device of claim 26, wherein the first portions of the gates comprise doped polysilicon, and wherein the second portions of the gates comprise undoped polysilicon.

28. The power semiconductor device of claim 27, wherein the at least one integrated polysilicon device, the gate connector, and the second portions of the gates comprise portions of a same polysilicon layer.

29. The power semiconductor device of claim 25, wherein the gate connector has a same conductivity as the second portions of the gates.

30. The power semiconductor device of claim 25, wherein the at least one integrated polysilicon device is electrically isolated from the gate connector devoid of an inter-polysilicon dielectric layer therebetween.

31.-43. (canceled)
